(19) United States
(12) Patent Application Publication
(10) Pub. No.: US 2025/0370042 A1
(43) Pub. Date: Dec. 4, 2025

(54) CLOCK SIGNAL CONTROL FOR SCAN-CHAIN TESTING

(71) Applicant: TEXAS INSTRUMENTS INCORPORATED, Dallas, TX (US)

(72) Inventors: Devanathan Varadarajan, Allen, TX (US); Eric Von Dohlen, Cypress, TX (US); Francisco Cano, Sugar Land, TX (US)

(21) Appl. No.: 18/680,724

(22) Filed: May 31, 2024

(51) Int. Cl. G01R 31/3185

(52) U.S. Cl. CPC G01R 31/318552; G01R 31/318575; G01R 31/318594

(57) ABSTRACT

In an embodiment, a system includes control circuitry to enable different clock signals. The control circuitry is configured to enable a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The control circuitry is further configured to, during the first and second idle portions, enable a second clock signal supplied to a different device coupled to the power supply.

### TECHNICAL FIELD

This disclosure relates generally to an electronic system and method, and, in particular embodiments, to clock signal control during scan-chain testing.

### BACKGROUND

In embedded systems, a system-on-chip (SoC) may include various components that function to provide functionality of an application or software program. For example, the SoC may include one or more processors (e.g., central processing units (CPUs), digital signal processors (DSPs)) that can execute instructions of the application to enable such functionality. Each of the processors may include sets of logic devices (e.g., flip-flops) that store data during operation of the processors.

To ensure proper functionality of the logic devices, the logic devices may undergo scan-chain testing whereby test data is provided to the logic devices and compared to reference data to identify issues with the logic devices. During a scan-chain test, a set of logic devices may receive a clock signal that controls states of the logic devices. The clock signal may be gated or slowed down while transitioning between different parts of the test. During the transitional periods when no clock signal is provided to the logic devices, noise may be created in a supply voltage driving each of the processors (e.g., across a voltage domain).

### SUMMARY

Disclosed herein are improvements to scan-chain testing, and particularly, to power distribution noise and supply power noise during such testing. One example embodiment includes a system. The system includes control circuitry to enable different clock signals. The control circuitry is configured to enable a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The control circuitry is further configured to, during the first and second idle portions, enable a second clock signal supplied to a different device coupled to the power supply.

In another example embodiment, a device is provided that includes a first processor coupled with one or more computer readable storage media and program instructions stored on the one or more computer readable storage media that, based on being read and executed by the processor, direct a second processor to perform various functions. For example, the program instructions may direct the second processor to enable a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The program instructions may further direct the second processor to, during the first and second idle portions, enable a second clock signal supplied to a different device coupled to the power supply.

In yet another example embodiment, a system is provided that includes a first clock terminal, a second clock terminal, and control circuitry. The control circuitry is configured to enable, via the first clock terminal, a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The control circuitry is further configured to, during the first and second idle portions, enable, via the second clock terminal, a second clock signal supplied to a different device coupled to the power supply.

In another example embodiment, a method of operating a device is provided. The method includes enabling a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The method also includes, during the first and second idle portions, enabling a second clock signal supplied to a different device coupled to the power supply.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates an example system configurable to enable clock signals during scan-chain tests in an implementation;

FIG. 2 illustrates a series of steps for enabling different clock signals during portions of a scan test in an implementation;

FIG. 3 illustrates an example system configurable to control scan-chain testing in an implementation;

FIG. 4 illustrates example graphical representations of signals produced by a system in an implementation;

FIG. 5 illustrates example graphical representations of signals produced by a system in an implementation; and

FIG. 6 illustrates example operating environments configurable to enable clock signals during scan-chain tests in an implementation.

FIG. 7 illustrates an example computer system that may be used in an implementation.

The drawings are not necessarily drawn to scale. In the drawings, like reference numerals designate corresponding parts throughout the several views. In some examples, components or operations may be separated into different blocks or may be combined into a single block.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates the various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Existing techniques to reduce noise introduced into the power supply of a system may attempt to reduce the duration of the transitional periods, gradually ramp the frequency of the clock signal during the transitional periods, or reduce the amount of power supplied to processors during a test. However, the existing techniques fail to address test time, scalability, and programmability considerations. For example, a solution may eliminate transitional periods by continuously providing the clock signal during testing. However, such designs may require additional components dedicated to pipelining techniques, which could increase overhead and cost. Another solution may slowly decrease the clock frequency during a first transitional period and slowly increase the clock frequency during a second transitional period to reduce such noise. However, such designs may use a low shift frequency during testing, which may impact the duration of a test increase cost. Another solution may reduce power provided to components of the system, but test time issues may arise, and reduced power may also result in lower range of testing capabilities.

Discussed herein are enhanced components, techniques, systems, and methods related to scan-chain testing, and particularly, to reducing power supply noise during such testing. During scan-chain testing, noise introduced into the power supply can cause issues with the power supply and devices driven by the power supply. To alleviate such noise and correlated issues, some embodiments may enable additional clock signals during portions of a scan-chain test to introduce signals within the power supply that offsets ripples in the voltage output by the power supply.

Often, devices including logic elements undergo testing to ensure accurate and efficient operation thereof. An example of such testing includes scan-chain testing whereby the logic elements are transitioned to a scan mode and supplied with scan data and a clock signal, transitioned to a functional mode and supplied with functional data, then transitioned back to the scan mode to verify whether the logic elements output expected results. Accordingly, a scan-chain test may include a scan-in cycle, a functional capture cycle, and a scan-out cycle. Between each cycle, the clock signal that drives operations of the logic elements may be paused or gated (e.g., transition to a low logical state (“0”)) while a scan enable signal transitions from high-to-low or low-to-high. These gaps between each of the cycles when signals input to the logic elements transition between logical states can introduce noise in the power supply that drives each of the devices of a system.

Existing solutions attempt to address such noise in the power supply in a number of different ways. For example, one solution eliminates or reduces these gaps to decrease the amount of noise introduced in the power supply. In another example, a solution decreases the amount of power supplied to the logic elements to reduce the amount of noise. However, the previous solutions increase both the time it takes to perform a scan-chain test and the cost and number of components required in a system to perform the scan-chain test.

In some embodiments, a system may inject a programmable and dynamic clock signal into a device separate from the device-under-test but within the same voltage domain to offset the noise. In this way, while the device-under-test may create noise during the gaps between cycles of the scan-chain test, the other device can balance out the noise based on the additional clock cycle provided to it during the gaps. Advantageously, such a system may identify inactive devices in the same voltage domain as a device-under-test and provide clock signals to one or more of the inactive device to reduce noise caused by impedance mismatches and shift periods, or idle portions, of a scan-chain test without utilizing additional components and cost, without reducing power provided to devices-under-test, or without reducing transition speed between portions of a scan-chain test.

One example embodiment includes a system. The system includes control circuitry to enable different clock signals. The control circuitry is configured to enable a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The control circuitry is further configured to, during the first and second idle portions, enable a second clock signal supplied to a different device coupled to the power supply.

In another example embodiment, a device is provided that includes a first processor coupled with one or more computer readable storage media and program instructions stored on the one or more computer readable storage media that, based on being read and executed by the processor, direct a second processor to perform various functions. For example, the program instructions may direct the second processor to enable a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The program instructions may further direct the second processor to, during the first and second idle portions, enable a second clock signal supplied to a different device coupled to the power supply.

In yet another example embodiment, a system is provided that includes a first clock terminal, a second clock terminal, and control circuitry. The control circuitry is configured to enable, via the first clock terminal, a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The control circuitry is further configured to, during the first and second idle portions, enable, via the second clock terminal, a second clock signal supplied to a different device coupled to the power supply.

In another example embodiment, a method of operating a device is provided. The method includes enabling a first clock signal to drive a device-under-test coupled to a power supply. The first clock signal includes a first portion that includes a first set of clock cycles, a second portion that includes a second set of clock cycles, a third portion that includes a third set of clock cycles, a first idle portion between the first portion and the second portion, and a second idle portion between the second portion and the third portion. The method also includes, during the first and second idle portions, enabling a second clock signal supplied to a different device coupled to the power supply.

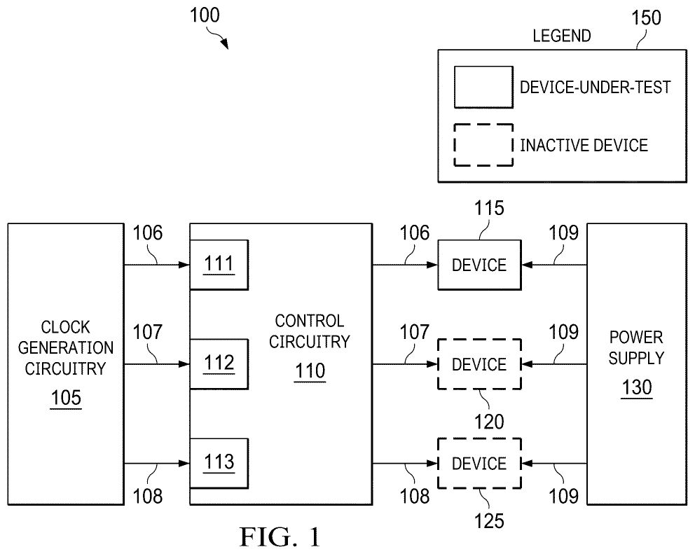

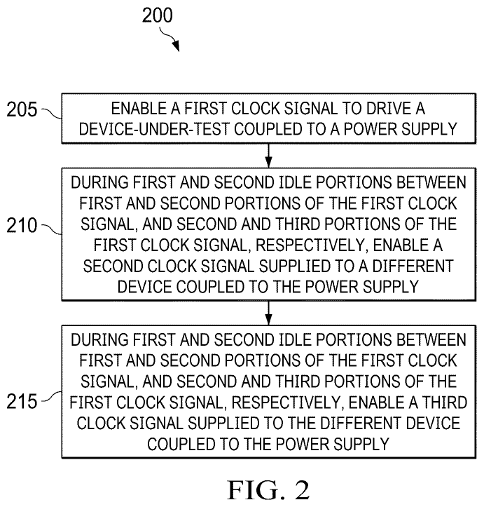

FIG. 1 illustrates an example system configurable to enable clock signals during scan-chain tests in an implementation. FIG. 1 shows system 100, which includes clock generation circuitry 105, control circuitry 110, devices 115, 120, and 125, and power supply 130. In various embodiments, control circuitry 110 may be configured to perform clock control operations, such as method 200 of FIG. 2.

In various examples, system 100 may be representative of a system capable of performing various operations enabled by devices 115, 120, and 125, such as via the execution of program instructions. To ensure devices 115, 120, and 125 operate as intended, system 100 may be capable of performing test operations on devices 115, 120, and 125 during run-time operations of devices 115, 120, and 125, or during a pre-operation testing period. System 100 may be an embedded system or a system-on-chip, such as a microcontroller, and each of devices 115, 120, and 125 may be a processing core of the embedded system, such as a central processing unit (CPU), a digital signal processor (DSP), a field-programmable gate array (FPGA), a general processing unit, or the like.

Devices 115, 120, and 125 may be operated or tested using one or more clock signals, such as clock signals 106, 107, and 108. Clock signals 106, 107, and 108 may be generated and provided to devices 115, 120, and 125 by clock generation circuitry 105. Clock generation circuitry 105 may be representative of one or more circuits capable of generating clock signals, e.g., at different frequencies and providing the clock signals to control circuitry 110 of system 100. In some examples, clock generation circuitry 105 may be included on-chip, or as part of embedded system 100. In some examples, clock generation circuitry 105 may be off-chip, or external relative to other components of system 100.

Control circuitry 110 may be representative of one or more circuits capable of receiving clock signals 106, 107, and 108 from clock generation circuitry 105 at pins 111, 112, and 113, respectively, and providing one or more of the clock signals downstream to devices 115, 120, and/or 125 at different intervals of time and/or for different durations based on desired operations of devices 115, 120, and 125. In some embodiments, control circuitry 110 may include clock generation circuitry 105, or elements thereof, and may generate and output the clock signals to devices 115, 120, and/or 125.

In some embodiments, control circuitry 110 may include one or more processors, processing cores, or processing circuitry capable of executing program instructions stored on a memory of control circuitry 110, or a memory external to control circuitry 110, that enables functionality thereof, such as providing the clock signals to different devices at various times. Examples of the processors may include one or more central processing units, general purpose processing units, field-programmable gate arrays, application-specific integrated circuits, digital signal processors, and the like.

In some embodiments, pins 111, 112, and 113 may be representative of pins, pads, ports, or connector devices of system 100 configured to couple to clock generation circuitry 105 to receive clock signals 106, 107, and 108, respectively. In some embodiments, control circuitry 110 may include clock generation circuit 105 (e.g., in an integrated circuit), and thus, might not include pins 111, 112, and 113.

In various embodiments, control circuitry 110 may be configured to perform clock control operations, such as method 200 of FIG. 2, e.g., to enable and provide the clock signals to devices 115, 120, and/or 125, or disable and gate the clock signals to prevent the clock signals from being provided to devices 115, 120, and/or 125.

Devices 115, 120, and 125 may be representative of different processing devices (e.g., a CPU, a DSP) capable of performing operations to enable functionality of system 100. Devices 115, 120, and 125 may be coupled to power supply 130, which can provide a supply voltage 109 to devices 115, 120, and 125 to power the devices. In some embodiments, devices 115, 120, and 125 may be included in the same voltage domain with respect to one another (powered by the same voltage).

During testing operations, components of devices 115, 120, and 125 may be tested to ensure accuracy and proper function of devices 115, 120, and 125. More specifically, each of devices 115, 120, and 125 may include sets of flip-flops, latches, and other logic gates or devices capable of storing and outputting logical states of input signals based on a clock signal received by the devices. Control circuitry 110 may enable a testing mode to test the logic components of devices 115, 120, and/or 125 by providing a scan enable signal and a clock signal (e.g., clock signal 106) to the logic devices.

A device undergoing a scan-chain test may be referred to herein as a device-under-test, which is denoted by a solid black box in FIG. 1 according to legend 150. A device not currently undergoing a scan-chain test may be referred to herein as an inactive device with respect to testing, which is denoted by a dashed black box in FIG. 1 according to legend 150. As illustrated in FIG. 1, device 115 may be a device-under-test, while devices 120 and 125 may be inactive devices. However, other variations or combinations may be contemplated.

By way of example, in operation, control circuitry 110 may perform a scan-chain test on device 115 over a scan cycle. The scan-chain test may include three parts: a scan-in portion, a functional capture portion, and a scan-out portion, each having a respective duration.

During the scan-in portion, control circuitry 110 may provide the scan enable signal and clock signal 106 to device 115. Device 115 may be configured to store various logical state values corresponding to scan data based on clock signal 106. In various examples, clock signal 106 may include a first set of clock cycles during the scan-in portion of the scan-chain test. The number of clock cycles and the frequency or duty cycle thereof may be based on the duration of a respective portion (e.g., the scan-in portion), an amount of voltage consumed by device 115 during the scan-in portion, and an impedance of device 115, among other factors. For each clock cycle, one or more components of device 115 may store and/or output a value to another one or more components.

Next, during the functional capture portion, control circuitry 110 may be configured to stop providing the scan enable signal to device 115. In some embodiments, the scan enable signal may transition from a high logical state (e.g., “1”) to a low logical state (e.g., “0”). During this time, functional data may be provided to device 115. In various examples, clock signal 106 may include a second set of clock cycles during the functional portion of the scan-chain test. The number of clock cycles in the second set of clock cycles may be based on one or more of the aforementioned factors. Lastly, during the scan-out portion, control circuitry 110 may be configured to provide the scan enable signal to device 115 to re-enable testing of the logic components and to determine whether the components are functioning as intended or are faulty. In various examples, clock signal 106 may include a third set of clock cycles during the scan-out portion, the number of which may be based on one or more of the factors. In some embodiments, the number of clock cycles in the first set and the second set may be the same.

Between the scan-in portion and the functional capture portion, and between the functional capture portion and the scan-out portion, there may be a first idle portion and a second idle portion, respectively. During the idle portions, clock signal 106 may be in the low logical state for an idle duration. In various examples, the idle portions may cause noise in supply voltage 109, and thus, in power supply 130. Accordingly, control circuitry 110 may be configured to provide one or more additional clock signals (e.g., clock signal 107, clock signal 108) to one or more inactive devices (e.g., device 120, device 125) to offset the noise.

Following the above example, control circuitry 110 may be configured to provide clock signal 107 to device 120, which may be an inactive device in this example. Clock signal 107 may include a fourth set of clock cycles during the first idle portion and a fifth set of clock cycles during the second idle portion. In some examples, the number of clock cycles in the fourth and fifth sets may be the same. In some examples, the number of clock cycles in the fourth and fifth sets may be different. The number of clock cycles may be determined based on the duration of the idle portions, an amount of voltage consumed by device 115 during the scan-chain test, and an impedance of device 115 or device 120, among other factors. In this way, while clock signal 106 may include gaps between sets of clock cycles during a scan-chain test, clock signal 107 may include sets of clock cycles to fill-in the gaps, such that supply voltage 109 is balanced during testing of one or more of devices 115, 120, and/or 125.

Additionally, control circuitry 110 may be further configured to provide clock signal 108 to device 120. Clock signal 108 may include a sixth set of clock cycles out-of-phase relative to clock signals 106 and 107. For example, the sixth set of clock cycles may be 180-degrees out-of-phase relative to phases of clock signals 106 and 107. The phase and number of clock cycles of clock signal 108 may be determined based on the impedance of device 115. In this way, by providing clock signal 108 to device 120, control circuitry 110 may reduce or eliminate resonant ringing, among other interference, within supply voltage 109 and power supply 130.

Advantageously, control circuitry 110 may identify inactive devices in the same voltage domain as a device-under-test and provide clock signals to an inactive device to reduce noise caused by impedance mismatches and shift periods, or idle portions, of a scan-chain test without utilizing additional components and cost, without reducing power provided to devices-under-test, or without reducing transition speed between portions of a scan-chain test.

FIG. 2 illustrates a series of steps for enabling different clock signals during portions of a scan test in an implementation. FIG. 2 shows method 200, which includes various steps related to clock signal enablement that reference elements of FIG. 1. In various embodiments, method 200 may be implemented by a controller or control circuitry of a system, such as control circuitry 110 of system 100 of FIG. 1. Accordingly, method 200 may be implemented in software, hardware, firmware, or combinations or variations thereof.

In operation 205, control circuitry 110 enables a first clock signal, clock signal 106, to drive device 115 during a scan-chain test. Device 115 may be representative of a processing device of a system that includes sets of flip-flops, latches, and other logic gates or devices capable of storing and outputting logical states of input signals during operation. Device 115 may be coupled to control circuitry 110 and power supply 130 to receive clock signal 106 and supply voltage 109, respectively, among other inputs.

Control circuitry 110 may be representative of one or more circuits capable of receiving clock signals 106, 107, and 108 from clock generation circuitry 105 at pins 111, 112, and 113, respectively, and providing one or more of the clock signals downstream to devices 115, 120, and/or 125 at different intervals of time and/or for different durations based on desired operations of devices 115, 120, and 125.

During the scan-chain test, the sets of flip-flops, latches, and other logic gates of device 115 may be operated and tested based on clock signal 106. Control circuitry 110 may enable the scan-chain test by providing a scan enable signal and clock signal 106 to the logic devices. Here, device 115 may be referred to herein as a device-under-test, while other devices of a system not undergoing a scan-chain test may be referred to as inactive devices.

Control circuitry 110 may perform a scan-chain test on device 115 over a scan cycle based on clock signal 106. The scan-chain test may include three parts: a scan-in portion, a functional capture portion, and a scan-out portion, each having a duration. During the scan-in portion, control circuitry 110 may provide the scan enable signal and clock signal 106 to device 115. Device 115 may be configured to store various logical state values corresponding to scan data based on clock signal 106. In various examples, clock signal 106 may include a first set of clock cycles during the scan-in portion of the scan-chain test. The number of clock cycles and the frequency or duty cycle thereof may be based on the duration of a respective portion (e.g., the scan-in portion), an amount of voltage consumed by device 115 during the scan-in portion, and an impedance of device 115, among other factors. For each clock cycle, one or more components of device 115 may store and/or output a value to another one or more components. Next, during the functional capture portion, control circuitry 110 may be configured to stop providing the scan enable signal to device 115. In other words, the scan enable signal may transition from a high logical state (e.g., “1”) to a low logical state (e.g., “0”). During this time, functional data may be provided to device 115. In various examples, clock signal 106 may include a second set of clock cycles during the functional capture portion of the scan-chain test. The number of clock cycles in the second set of clock cycles may be based on one or more of the aforementioned factors. Lastly, during the scan-out portion, control circuitry 110 may be configured to provide the scan enable signal to device 115 to re-enable testing of the logic components and to determine whether the components are functioning as intended or are faulty. In various examples, clock signal 106 may include a third set of clock cycles during the scan-out portion, the number of which may be based on one or more of the factors. In some examples, the number of clock cycles in the first set and the second set may be the same.

Between the scan-in portion and the functional capture portion, and between the functional capture portion and the scan-out portion, there may be a first idle portion and a second idle portion, respectively. During the idle portions, clock signal 106 may be in the low logical state for an idle duration. In various examples, the idle portions may cause noise in supply voltage 109, and thus, in power supply 130. Accordingly, in operation 210, during the first and second idle portions, control circuitry 110 may be configured to provide clock signal 107 to a different, inactive device (e.g., device 120, device 125) also coupled to power supply 130 to offset the noise.

Clock signal 107 may include a fourth set of clock cycles during the first idle portion and a fifth set of clock cycles during the second idle portion. In some examples, the number of clock cycles in the fourth and fifth sets may be the same. In some examples, the number of clock cycles in the fourth and fifth sets may be different. The number of clock cycles may be determined based on the duration of the idle portions, an amount of voltage consumed by device 115 during the scan-chain test, and an impedance of device 115 or device 120, among other factors. In this way, while clock signal 106 may include gaps between sets of clock cycles during a scan-chain test, clock signal 107 may include sets of clock cycles to fill-in the gaps, such that supply voltage 109 is balanced during testing of one or more of devices 115, 120, and/or 125.

Additionally, in operation 215, control circuitry 110 may be further configured to provide clock signal 108 to device 120 during the first and second idle portions. Clock signal 108 may include a sixth set of clock cycles out-of-phase relative to clock signals 106 and 107. For example, the sixth set of clock cycles may be 180-degrees out-of-phase relative to phases of clock signals 106 and 107. The phase and number of clock cycles of clock signal 108 may be determined based on the impedance of device 115. In this way, by providing clock signal 108 to device 120, control circuitry 110 may advantageously reduce or eliminate resonant ringing, among other interference, within supply voltage 109 and power supply 130.

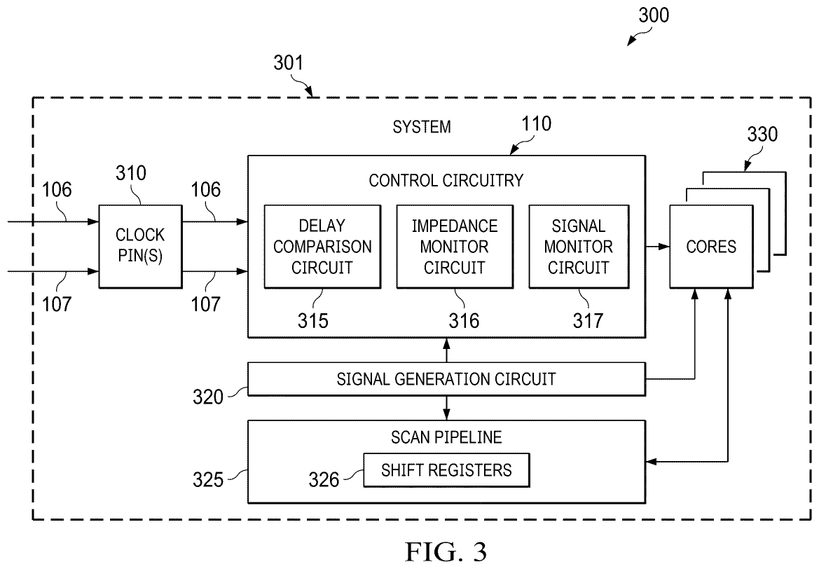

FIG. 3 illustrates an example system configurable to control scan-chain testing in an implementation. FIG. 3 shows system 301 in operating environment 300. System 301 includes clock pins 310, control circuitry 110, signal generation circuit 320, cores 330, and scan pipeline 325. Control circuitry 110 further includes delay comparison circuit 315, impedance monitor circuit 316, and signal monitor circuit 317. Scan pipeline 325 further includes shift registers 326.

In various examples, system 301 may be representative of a system capable of performing various operations enabled by cores 330, such as via the execution of program instructions. To ensure cores 330, and components thereof, operate as intended, system 301 may be capable of performing test operations on cores 330 during run-time operations or during pre-operation testing periods. System 301 may be an embedded system or a system-on-chip, such as a microcontroller, and each of cores 330 may be representative of a processing core of the embedded system, such as a central processing unit (CPU), a digital signal processor (DSP), a field-programmable gate array (FPGA), a general processing unit, or the like.

Cores 330 may be operated or tested using one or more clock signals, such as clock signals 106 and 107. Clock signals 106 and 107 may be generated and provided to elements of system 301 by control circuitry 110 via clock pins 310. In various examples, clock pins 310 may be coupled to a clock generation circuitry (e.g., clock generation circuitry 105), external or internal to system 301, which can generate and provide the clock signals to system 301. In some examples, clock pins 310 may include multiple pins, each coupled to receive an individual clock signal. In some examples, clock pins 310 may include a single pin coupled to receive a single clock signal having different frequencies.

Control circuitry 110 may be representative of one or more circuits capable of receiving clock signals 106 and 107 from clock generation circuitry 105 at clock pins 310 and providing one or more of the clock signals downstream to cores 330 at different intervals of time and/or for different durations based on desired operations of cores 330. In various examples, control circuitry 110 may be configured to perform clock control operations, such as method 200 of FIG. 2, to enable and provide the clock signals to cores 330, or disable and gate the clock signals to prevent the clock signals from being provided to cores. To perform the clock control operations, control circuitry 110 may include delay comparison circuit 315, impedance monitor circuit 316, and signal monitor circuit 317.

Delay comparison circuit 315 may be representative of one or more components capable of identifying a delay between clock signals (e.g., clock signal 106 and clock signal 107) and configuring a clock signal based on the delay. For example, delay comparison circuit 315 may increase or reduce the number of clock cycles within a clock signal, the duty cycle of a clock signal, or other parameters of the clock signal based on an identified delay between clock cycles of clock signals.

Impedance monitor circuit 316 may be representative of one or more components capable of identifying an impedance of a processing system, device, or core and configuring a clock signal based on the delay. For example, impedance monitor circuit 316 may increase or reduce the number of clock cycles within a clock signal, the duty cycle of a clock signal, the phase of a clock signal relative to another clock signal, or other parameters of the clock signal based on an impedance exceeding a threshold impedance value.

Signal monitor circuit 317 may be representative of one or more components capable of identifying current or voltage values consumed by a processing system, device, or core, and/or a current or voltage value of a supply power provided to cores 330 by a power supply (e.g., power supply 130). For example, signal monitor circuit 317 may increase or reduce the number of clock cycles within a clock signal, the duty cycle of a clock signal, or other parameters of the clock signal based on the current and/or voltage values.

Control circuitry 110 may be configured to provide clock signal 106 and/or clock signal 107 to cores 330 based on an input from signal generation circuit 320. Signal generation circuit 320 may be representative of one or more components capable of providing signals to enable run-time operations or test operations of cores 330. For example, signal generation circuit 320 may enable a scan-chain test of one or more of cores 330 by providing a scan enable signal to cores 330. Signal generation circuit 320 may be coupled to scan pipeline 325. Scan pipeline 325 may include shift registers 326, which may store scan data and/or functional data that may be used during a scan-chain test.

In operation, signal generation circuit 320 enables a scan-chain test for a first core of cores 330. Signal generation circuit 320 can provide the scan enable signal to control circuitry 110, to scan pipeline 325, and to cores 330. In response, control circuitry 110 can provide clock signal 106 to the first cores with which the first core can perform a scan-chain test over a scan cycle. The scan cycle may include three parts: a scan-in portion, a functional capture portion, and a scan-out portion, each having a duration.

During the scan-in portion, control circuitry 110 may provide clock signal 106 to the first core, and signal generation circuit 320 may provide the scan enable signal having a high logical value. The first core may be configured to store various logical state values corresponding to scan data based on clock signal 106 and can provide scan data to scan pipeline 325. In various examples, clock signal 106 may include a first set of clock cycles during the scan-in portion of the scan-chain test. The number of clock cycles and the frequency or duty cycle thereof may be based on the duration of a respective portion (e.g., the scan-in portion), an amount of voltage consumed by device 115 during the scan-in portion, and an impedance of the first core, among other factors, as determined by components of control circuitry 110.

During the functional capture portion, signal generation circuit 320 may be configured to stop providing the scan enable signal to the first core, and control circuitry 110 may continue to provide clock signal 106 to the first core. In some embodiments, the scan enable signal may transition from a high logical state (e.g., “1”) to a low logical state (e.g., “0”). During this time, the first core may obtain functional data from scan pipeline 325. In various examples, clock signal 106 may include a second set of clock cycles during the functional capture portion of the scan-chain test. The number of clock cycles in the second set of clock cycles may be based on one or more of the aforementioned factors.

During the scan-out portion, control circuitry 110 may be configured to provide the scan enable signal to the first core to re-enable testing of the logic components and to determine whether the components are functioning as intended or are faulty. In various examples, clock signal 106 may include a third set of clock cycles during the scan-out portion, the number of which may be based on one or more of the factors. In some examples, the number of clock cycles in the first set and the second set may be the same.

Between the scan-in portion and the functional capture portion, and between the functional capture portion and the scan-out portion, there may be a first idle portion and a second idle portion, respectively. During the idle portions, clock signal 106 may be in the low logical state for an idle duration. In various examples, the idle portions may cause noise in the supply voltage, and thus, in the power supply coupled to cores 330. To offset this noise, control circuitry 110 may be configured to provide clock signal 107 to one or more inactive cores (i.e., cores not under test).

Following the above example, control circuitry 110 may be configured to provide clock signal 107 to a second core of cores 330, which may be an inactive device in this example. Clock signal 107 may include a fourth set of clock cycles during the first idle portion and a fifth set of clock cycles during the second idle portion. In some examples, the number of clock cycles in the fourth and fifth sets may be the same. In some examples, the number of clock cycles in the fourth and fifth sets may be different. The number of clock cycles may be determined based on the duration of the idle portions, an amount of voltage consumed by the second core during the scan-chain test, and an impedance of cores 330 or system 301, among other factors as determined by components of control circuitry 110, such as delay comparison circuit 315, impedance monitor circuit 316, and signal monitor circuit 317. In this way, while clock signal 106 may include gaps between sets of clock cycles during a scan-chain test, clock signal 107 may include sets of clock cycles to fill-in the gaps, such that the supply voltage driving each of cores 330 is balanced, or less noisy, during testing of one or more of cores 330.

Advantageously, control circuitry 110 may identify inactive devices in the same voltage domain as a device-under-test and provide clock signals to an inactive device to reduce noise caused by impedance mismatches and shift periods, or idle portions, of a scan-chain test without utilizing additional components and cost, without reducing power provided to devices-under-test, or without reducing transition speed between portions of a scan-chain test.

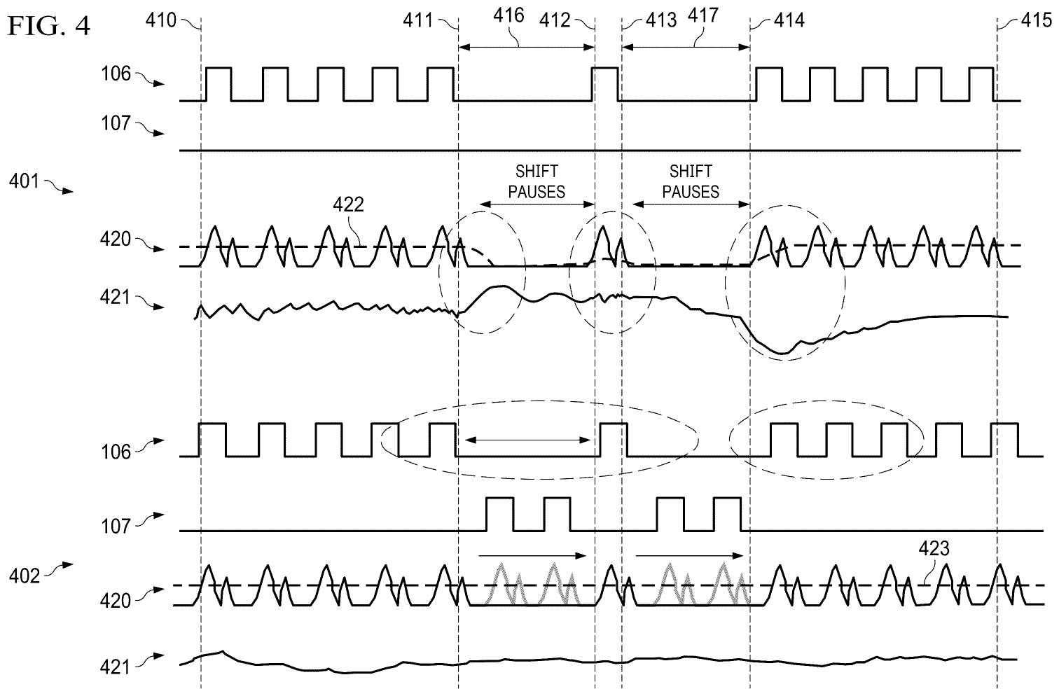

FIG. 4 illustrates example graphical representations of signals produced by a system in an implementation. FIG. 4 shows graphical representations 401 and 402, which both include waveforms representing clock signal 106, clock signal 107, current 420, and voltage 421. Each waveform may include a set of values (e.g., logical state values, output values) varying over a duration of a scan cycle. Graphical representations 401 and 402 may include results and respective waveforms of separate scenarios that may occur at different times and that may be produced using different systems despite showing a shared time axis in FIG. 4.

Referring first to graphical representation 401, graphical representation 401 includes various waveforms produced by components of a system (e.g., system 100 of FIG. 1, system 301 of FIG. 3) during a scan-chain test. A first waveform may correspond to clock signal 106 and show a number of clock signals in accordance with a clock pattern during the scan-chain test. A second waveform may correspond to clock signal 107, which may be gated (i.e., includes no clock cycles) during the scan-chain test performed in this example. In some embodiments, the scan-chain test may be performed without introducing an additional clock signal to offset noise generated in a power supply (e.g., power supply 130). A third waveform may correspond to current 420, which may correspond to current values produced by a device-under test (e.g., device 115) during the scan-chain test. A fourth waveform may correspond to voltage 421, which may correspond to voltage values of the supply power (e.g., supply voltage 109) driving the device-under-test during the scan-chain test.

At time 410, control circuitry (e.g., control circuitry 110) may provide a scan enable signal having a high logical state (e.g., “1”) and clock signal 106 to a device-under-test to begin the scan-chain test of the device-under-test. From time 410 to time 411, clock signal 106 transitions between the low logical state (e.g., “0”) and the high logical state a number of times from time 410 to time 411 based on a number of clock cycles in the first portion of the scan-chain test. As the device-under-test operates in accordance with the scan-chain test, the device-under-test may produce current 420 having non-zero values and may produce ripples in voltage 421.

In this example, clock signal 106 may include five clock cycles between time 410 and time 411. The time interval between times 410 and 411 may be referred to as the scan-in portion of the scan-chain test. During the scan-in portion, scan data may be provided to components of the device-under-test (e.g., flip-flops). In some examples, clock signal 106 may include fewer or additional clock cycles or may include clock cycles having a different pattern or duty cycle during the scan-in portion.

At time 411, clock signal 106 may transition from the high logical state to the low logical state and remain in the low logical state for a duration over an idle portion 416 between time 411 and time 412. At this time, the scan enable signal may transition from the high logical state to the low logical state. As clock signal 106 and the scan enable signal remain in the low logical state between times 411 and 412, current 420 produced by the device-under-test may fall to zero (or approximately zero) during idle portion 416. However, voltage 421 may increase due to noise introduced into the power supply based on the transition of the scan enable signal and clock signal 106 and the pause in clock cycles of clock signal 106 during idle portion 416.

At time 412, clock signal 106 transitions from the low logical state to the high logical state, which may cause the device-under-test to perform a functional capture portion of the scan-chain test from time 412 to time 413. During the functional capture portion, functional data may be provided to the device-under-test. The device-under-test may produce current 420 having non-zero values and may produce ripples in voltage 421.

As illustrated by graphical representation 401, clock signal 106 may include a single clock cycle during the functional capture portion. However, in some examples, clock signal 106 may include additional clock cycles, which may have a pattern, frequency, and duty cycle based on a desired operation of the device-under-test during the functional capture portion of the scan-chain test.

At time 413, clock signal 106 transitions from the high logical state to the low logical state and remains in the low logical state for a duration over an idle portion 417 between time 413 and time 414. As clock signal 106 and the scan enable signal remain in the low logical state between times 413 and 414, current 420 produced by the device-under-test may fall to zero (or approximately zero) again. However, voltage 421 may increase or decrease due to noise introduced into the power supply based on the pause in clock cycles during idle portion 417.

At time 414, clock signal 106 transitions from the low logical state to the high logical state and transitions between the low logical state and the high logical state a number of times from time 414 to time 415 based on a number of clock cycles. At this time, the scan enable signal may also transition from the low logical state to the high logical state to enable a scan-out portion of the scan-chain test. As the device-under-test operates in accordance with the scan-chain test, the device-under-test may produce current 420 having non-zero values and may produce ripples in voltage 421. However, due to the transition of the scan enable signal and clock signal 106 at time 414, voltage 421 may include a large swing in values based on noise created during idle portion 417.

Referring next to graphical representation 402, graphical representation 402 includes various waveforms produced by components of a system during a scan-chain test. However, unlike the scan-chain test performed using a single clock signal (clock signal 106) as illustrated in graphical representation 401, the scan-chain test illustrated in graphical representation 402 includes an additional clock signal (clock signal 107) to provide clock cycles continuously throughout the scan-chain test, which may offset noisy, unbalanced, portions of voltage 421 during idle portions 416 and 417 of the scan-chain test.

More specifically, between time 411 and time 412 during idle portion 416 and between time 413 and 414 during idle portion 417, clock signal 107 may transition between the low logical state and the high logical state a number of times or for a number of clock cycles to fill in a gap between clock cycles of clock signal 106 during idle portions 416 and 417. In various examples, the control circuitry may provide clock signal 107 to a different device not under test (e.g., device 120) that is coupled to and driven by the same power supply that drives the device-under-test.

In this example, clock signal 107 may include two clock cycles during idle portion 416 and two clock cycles during idle portion 417. The two sets of clock cycles of clock signal 107 may include the same duty cycle or frequency as each other and as the clock cycles of clock signal 106.

Clock signal 107 may be provided to the different device, or the device not under test, at a time, or with a delay, after time 411 and after time 413 that equals the amount of time between a transition from low-to-high or high-to-low of clock cycles of clock signal 106. In some embodiments, the clock cycles of clock signal 107 may fill in gaps where clock signal 106 is in the low logical state during idle portion 416 that, in effect, offsets noise and ripples in voltage 421 and produces similar values of current 420 among the devices as if clock signal 106 continued to transition between logical states during the duration of the scan-chain test. Thus, as illustrated in graphical representation 402, current 420 may include a consistent average value 423 throughout the scan-chain test unlike current 420 of graphical representation 401 that includes an average value 422 that falls to zero (or approximately zero) during idle portions 416 and 417, and noise 421 may include fewer ripples and reduced noise throughout the scan-chain test with the introduction of clock signal 107 to the different device during idle portions 416 and 417.

In some examples, clock signals 106 and 107 may include a different number of clock cycles in each portion of the scan-chain test and/or may include different duty cycles or patterns based on various factors. For example, the number of clock cycles, or the pattern thereof, may be based on impedance values of a system, device, or power supply, average voltage or current consumption of the device-under-test during the scan-chain test, or durations of each portion of the scan-chain test, among other factors. The control circuitry may identify such factors and enable or gate clock signals 106 and 107 at various times and for various durations over a scan cycle of a scan-chain test.

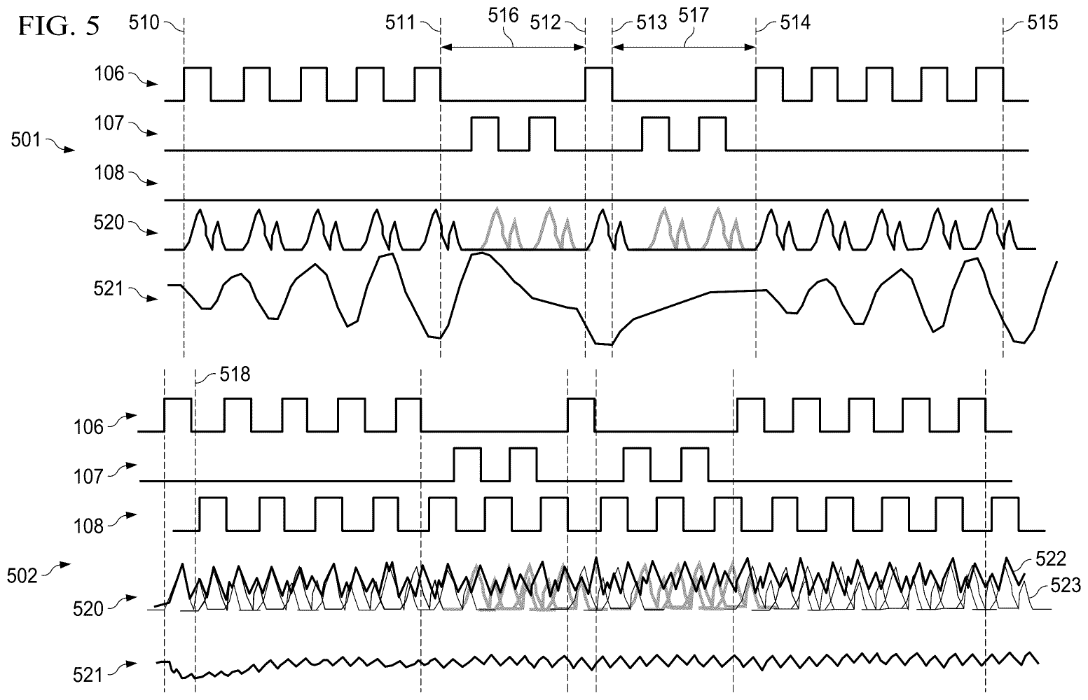

FIG. 5 illustrates example graphical representations of signals produced by a system in an implementation. FIG. 5 shows graphical representations 501 and 502, which both include waveforms representing clock signal 106, clock signal 107, clock signal 108, current 520, and voltage 521. Each waveform may include a set of values (e.g., logical state values, output values) varying over a duration of a scan cycle. Graphical representations 501 and 502 may include results and respective waveforms of separate scenarios that may occur at different times despite showing a shared time axis in FIG. 5.

Referring first to graphical representation 501, graphical representation 501 includes various waveforms produced by components of a system (e.g., system 100 of FIG. 1, system 301 of FIG. 3) during a scan-chain test. A first waveform may correspond to clock signal 106 and show a number of clock signals in accordance with a clock pattern during the scan-chain test. A second waveform may correspond to clock signal 107 and show a number of clock signals in accordance with a clock pattern during the scan-chain test. A third waveform may correspond to clock signal 108, which may be gated (i.e., includes no clock cycles) during the scan-chain test performed in this example. In other words, the scan-chain test may be performed without introducing a third clock signal to provide impedance matching for the system. A fourth waveform may correspond to current 520, which may correspond to current values produced by a device-under test (e.g., device 115) during the scan-chain test. A fifth waveform may correspond to voltage 521, which may correspond to voltage values of the supply power (e.g., supply voltage 109) driving the device-under-test during the scan-chain test.

At time 510, control circuitry (e.g., control circuitry 110) may provide a scan enable signal having a high logical state (e.g., “1”) and clock signal 106 to a device-under-test to begin the scan-chain test of the device-under-test. From time 510 to time 511, clock signal 106 transitions between the low logical state (e.g., “0”) and the high logical state a number of times from time 510 to time 511 based on a number of clock cycles in the first portion of the scan-chain test. As the device-under-test operates in accordance with the scan-chain test, the device-under-test may produce current 520 having non-zero values and a consistent average value and may produce ripples in voltage 521 that gradually increase based on impedance mismatches.

In this example, clock signal 106 may include five clock cycles between time 510 and time 511. The time interval between times 510 and 511 may be referred to as the scan-in portion of the scan-chain test. During the scan-in portion, scan data may be provided to components of the device-under-test (e.g., flip-flops). In some examples, clock signal 106 may include fewer or additional clock cycles or may include clock cycles having a different pattern or duty cycle during the scan-in portion.

At time 511, clock signal 106 may transition from the high logical state to the low logical state and remain in the low logical state for a duration over an idle portion 516 between time 511 and time 512. At this time, the scan enable signal may transition from the high logical state to the low logical state. After a delay, during idle portion 516, clock signal 107 may transition between the low logical state and the high logical state a number of times or for a number of clock cycles to fill in a gap between clock cycles of clock signal 106 during idle portion 516. In various examples, the control circuitry may provide clock signal 107 to a different device not under test (e.g., device 120) that is coupled to and driven by the same power supply that drives the device-under-test.

In this example, clock signal 107 may include two clock cycles during idle portion 516. The clock cycles of clock signal 107 may include the same duty cycle or frequency as each other and as the clock cycles of clock signal 106. Clock signal 107 may be provided to the different device at a time, or with a delay, after time 511 that equals the amount of time between a transition from low-to-high or high-to-low of clock cycles of clock signal 106. In other words, the clock cycles of clock signal 107 may fill in gaps where clock signal 106 is in the low logical state during idle portion 516 that, in effect, offsets noise and ripples in voltage 521 and produces similar values of current 520 among the devices as if clock signal 106 continued to transition between logical states during the duration of the scan-chain test. Thus, as illustrated in graphical representation 501, current 520 may include a consistent average value throughout the scan-chain test, and noise 521 may include few ripples and reduced noise throughout the scan-chain test with the introduction of clock signal 107 to the different device during idle portion 516.

At time 512, clock signal 106 transitions from the low logical state to the high logical state while clock signal 107 remains in the low logical state, which may cause the device-under-test to perform a functional capture portion of the scan-chain test from time 512 to time 513. During the functional capture portion, functional data may be provided to the device-under-test. The device-under-test may produce current 520, based on current produced from clock signals 106 and 107 oscillating, having non-zero values and may produce ripples in voltage 521. As illustrated by graphical representation 501, clock signal 106 may include a single clock cycle during the functional capture portion. However, in some examples, clock signal 106 may include additional clock cycles, which may have a pattern, frequency, and duty cycle based on a desired operation of the device-under-test during the functional capture portion of the scan-chain test.

At time 513, clock signal 106 transitions from the high logical state to the low logical state and remains in the low logical state for a duration over an idle portion 517 between time 513 and time 514. After a delay, during idle portion 517, clock signal 107 may transition between the low logical state and the high logical state a number of times or for a number of clock cycles to fill in a gap between clock cycles of clock signal 106 during idle portion 517.

In this example, clock signal 107 may include two clock cycles during idle portion 517. These clock cycles may have the same duty cycle or frequency as each other, as the clock cycles of clock signal 106, and as the other clock cycles of clock signal 107. The delay between time 513 and the time that clock signal 107 transitions from the low logical state to the high logical state may include the same amount of time as the delay between time 511 and the time that clock signal 107 transitions high during idle portion 516. Thus, with the addition of clock signal 107, as illustrated in graphical representation 501, current 520 may include a consistent average value throughout the scan-chain test, and voltage 521 may include few ripples and reduced noise throughout the scan-chain test with the introduction of clock signal 107 to the different device during idle portion 517.

At time 514, clock signal 106 transitions from the low logical state to the high logical state and transitions between the low logical state and the high logical state a number of times from time 514 to time 515 based on a number of clock cycles. At this time, the scan enable signal may also transition from the low logical state to the high logical state to enable a scan-out portion of the scan-chain test. As the device-under-test operates in accordance with the scan-chain test, the device-under-test may produce current 520, which includes current 523 based on current produced from clock signals 106 and 107 and current 522 based on current produced from clock signal 108, with non-zero values and may produce swings in voltage 521 that gradually increase over time.

Referring next to graphical representation 502, graphical representation 502 includes various waveforms produced by components of a system during a scan-chain test. However, unlike the scan-chain test performed using two clock signals (clock signal 106 and clock signal 107) as illustrated in graphical representation 501, the scan-chain test illustrated in graphical representation 502 includes an additional clock signal (clock signal 108) to provide phase-shifted clock cycles continuously throughout the scan-chain test, which may offset noise and gradual increases in voltage swings due to impedance mismatches in the system.

More specifically, the control circuitry may provide clock signal 108 to the different device continuously (e.g., with continuous periodic clock pulses) throughout the scan-chain test. Clock signal 108 may include a number of clock cycles and a clock pattern during each portion of the scan-chain test. The control circuitry may provide clock signal 108 to the different device (e.g., a device not under test) at time 518. In various embodiments, the device may receive clock signal 108. In some embodiments, clock signal 108 might be gated or might not be propagated to elements of the device for use in testing the device. At this time, clock signal 108 may transition from the low logical state to the high logical state. In various examples, clock signal 108 may include clock cycles having the same duty cycle or frequency as the clock cycles of clock signal 106 and clock signal 107. However, the clock cycles of clock signal 108 may be 180-degrees out-of-phase relative to the clock cycles of clock signals 106 and 107. Accordingly, the amount of time between time 510 and time 518 may be an amount of time such that clock signal 108 begins transitioning from low to high when clock signal 106 transitions from high to low. In this way, clock signal 108 may impact voltage 521 by reducing gradual increases in swings of values during the scan-chain test caused by impedance mismatches and create balanced, consistent values of voltage 521 throughout the scan-chain test.

In some examples, the control circuitry may provide clock signal 108 to a device other than the device-under-test and the different device that receives clock signal 107. In some examples, clock signal 108 may include clock signals that are a different number of degrees out-of-phase relative to the clock cycles of clock signals 106 and 107 (e.g., 90-degrees out-of-phase). Additionally, or instead, clock signal 108 may include a different number of clock cycles, a varied pattern, or the like based on the amount impedance mismatch within the system during a scan-chain test.

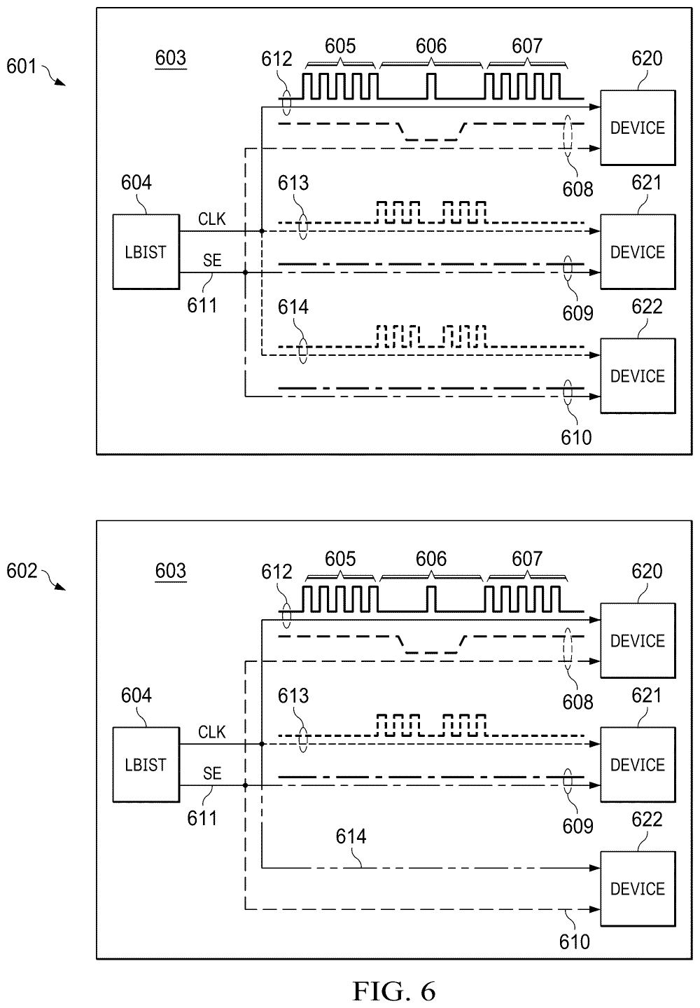

FIG. 6 illustrates example operating environments configurable to enable clock signals during scan-chain tests in an implementation. FIG. 6 shows operating environments 601 and 602, which both include system 603. System 603 includes logic built-in self-test (LBIST) 604 and devices 620, 621, and 622. In various embodiments, LBIST 604 may be configured to perform clock enablement operations, such as method 200 of FIG. 2.

In various examples, system 603 may be representative of a system capable of performing various operations enabled by devices 620, 621, and 622, such as via the execution of program instructions. To ensure devices 620, 621, and 622 operate as intended, system 603 may be capable of performing test operations on devices 620, 621, and 622 during run-time operations of devices 620, 621, and 622. System 603 may be an embedded system or a system-on-chip, such as a microcontroller, and each of devices 620, 621, and 622 may be a processing core of the embedded system, such as a central processing unit (CPU), a digital signal processor (DSP), a field-programmable gate array (FPGA), a general processing unit, or the like.

Devices 620, 621, and 622 may be operated or tested using one or more clock signals, such as clock signals 612, 613, and 614, respectively. Clock signals 612, 613, and 614 may be generated and provided to devices 620, 621, and 622, respectively, by LBIST 604. LBIST 604 may be representative of one or more circuits capable of performing self-testing operations to test accuracy and efficiency of operations of devices 620, 621, and 622. To perform self-testing operations, LBIST 604 may be configured to provide scan enable signals 608, 609, and 610 to devices 620, 621, and 622, respectively, and a respective clock signal to one or more of devices 620, 621, and 622.

Devices 620, 621, and 622 may be representative of different processing devices (e.g., a CPU, a DSP) capable of performing operations to enable functionality of system 603. Devices 620, 621, and 622 may be coupled to a power supply of system 603, which can provide a supply voltage to devices 620, 621, and 622 to power the devices. In other words, devices 620, 621, and 622 may be included in the same voltage domain with respect to one another.

Each of devices 620, 621, and 622 may include sets of flip-flops, latches, and other logic gates or devices capable of storing and outputting logical states of input signals based on a clock signal received by the devices. LBIST 604 may enable a testing mode to test the logic components of devices 620, 621, and 622 by providing scan enable signal 611 and a clock signal (e.g., clock signal 612) to the logic devices. A device undergoing a scan-chain test may be referred to herein as a device-under-test. A device not currently undergoing a scan-chain test may be referred to herein as an inactive device with respect to testing.

Referring first to operating environment 601, in operation, LBIST 604 may perform a scan-chain test on device 620. Thus, device 620 may be the device-under-test while devices 621 and 622 may be inactive devices. The scan-chain test may include three parts: a scan-in portion 605, a functional capture portion 606, and a scan-out portion 607, each having a duration.

During the scan-in portion 605, LBIST 604 may provide scan enable signal 608 at a high logical state and clock signal 612 to device 620. Additionally LBIST 604 may provide scan enable signals 609 and 610 to devices 621 and 622, respectively, however, scan enable signals 609 and 610 may remain in the logical low state. Device 620 may be configured to store various logical state values corresponding to scan data based on clock signal 612 and scan enable signal 608. In various examples, clock signal 612 may include a first set of clock cycles during the scan-in portion 605 of the scan-chain test. The number of clock cycles and the frequency or duty cycle thereof may be based on the duration of a respective portion (e.g., the scan-in portion 605), an amount of voltage consumed by device 620 during the scan-in portion, and an impedance of device 620 or of system 603, among other factors. For each clock cycle, one or more components of device 620 may store and/or output a value to another one or more components.

During the functional capture portion 606, LBIST 604 may be configured to transition scan enable signal 608 to the low logical state. During this time, functional data may be provided to device 620. In various examples, clock signal 612 may include a second set of clock cycles during the functional capture portion of the scan-chain test. The number of clock cycles in the second set of clock cycles may be based on one or more of the aforementioned factors. Also during this time, clock signals 613 and 614 provided to devices 621 and 622, respectively, may begin to transition between the logical low and logical high states for a number of clock cycles.

During the scan-out portion 607, LBIST 604 may be configured to transition scan enable signal 608 to the high logical state to re-enable testing of the logic components and to determine whether the components are functioning as intended or are faulty. In various examples, clock signal 612 may include a third set of clock cycles during the scan-out portion 607, the number of which may be based on one or more of the factors. In some examples, the number of clock cycles in the first set and the second set may be the same. Also, during the scan-out portion 607, clock signals 613 and 614 may include no clock cycles. In other words, clock signals 613 and 614 may remain in the low logical state.

Between the scan-in portion and the functional capture portion, and between the functional capture portion and the scan-out portion, there may be a first idle portion and a second idle portion, respectively. During the idle portions, clock signal 612 may be in the low logical state for an idle duration. In various examples, the idle portions may cause noise in supply voltage driving devices 620, 621, and 622. Accordingly, LBIST 604 may be configured to provide clock signals 613 and 614 to devices 621 and 622, respectively, during the functional capture portion of the scan-chain test. Clock signals 613 and 614 may include sets of clock cycles that fill in idle portions during the functional capture portion when clock signal 612 is in the low logical state. In some embodiments, clock signals 613 and 614 may include the same number of clock cycles, and the clock cycles may be synchronized for the duration of function portion 606.

Following the example illustrated in operating environment 601, clock signal 612 may include a fourth set of clock cycles during the first idle portion and a fifth set of clock cycles during the second idle portion. In some examples, the number of clock cycles in the fourth and fifth sets may be the same. In some examples, the number of clock cycles in the fourth and fifth sets may be different. The number of clock cycles may be determined based on the duration of the idle portions, an amount of voltage consumed by device 620 during the scan-chain test, and an impedance of the devices or the system, among other factors. In this way, while clock signal 612 may include gaps between sets of clock cycles during a scan-chain test, clock signals 613 and/or 614 may include sets of clock cycles to fill-in the gaps, such that the supply voltage is balanced during testing of one or more of devices 620, 621, and 622.

In other examples, such as one illustrated by graphical representation 602, LBIST 604 may provide clock signal 613 device 621 but might not provide clock signal 614 to device 622. In this way, LBIST 604 can gate clock signals 614 from being provided to device 622. LBIST 604 may determine to which inactive devices to provide a respective clock signal based on factors described above. Thus, LBIST 604 can dynamically adjust operations during run-time to offset noise in a power supply of system 603.

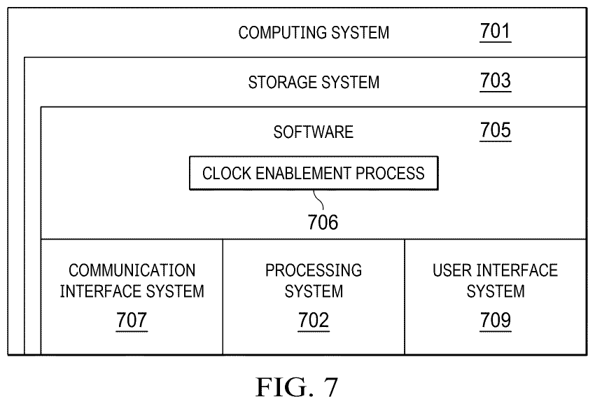

FIG. 7 illustrates an example computer system that may be used in an implementation. FIG. 7 illustrates computing system 701 to perform scan-chain testing and clock signal control during such testing according to an implementation of the present technology. Computing system 701 is representative of any system or collection of systems with which the various operational architectures, processes, scenarios, and sequences disclosed herein for memory access may be employed, such as system 100 or elements thereof, e.g., control circuitry 110, devices 115, 120, and 125, system 301 or elements thereof, e.g., cores 330, and system 603 or elements thereof, e.g., devices 620, 621, 622, and LBIST 604. Computing system 701 may be implemented as a single apparatus, system, or device or may be implemented in a distributed manner as multiple apparatuses, systems, or devices. Computing system 701 includes, but is not limited to, processing system 702, storage system 703, software 705, communication interface system 707, and user interface system 709 (optional). Processing system 702 is operatively coupled with storage system 703, communication interface system 707, and user interface system 709. Computing system 701 may be representative of a cloud computing device, distributed computing device, or the like.

Processing system 702 loads and executes software 705 from storage system 703, or alternatively, runs software 705 directly from storage system 703. Software 705 includes and implements address mapping process 706, which is representative of any of the clock control, clock enablement, scan-chain testing, and scan enablement processes discussed with respect to the preceding Figures. When executed by processing system 702 to provide clock signal enablement functions, software 705 directs processing system 702 to operate as described herein for at least the various processes, operational scenarios, and sequences discussed in the foregoing implementations. Computing system 701 may optionally include additional devices, features, or functionality not discussed for purposes of brevity.

Referring still to FIG. 7, processing system 702 may comprise a micro-processor and other circuitry that retrieves and executes software 705 from storage system 703. Processing system 702 may be implemented within a single processing device but may also be distributed across multiple processing devices or sub-systems that cooperate in executing program instructions. Examples of processing system 702 include general purpose central processing units, graphical processing units, digital signal processing units, data processing units, application specific processors, and logic devices, as well as any other type of processing device, combinations, or variations thereof.

Storage system 703 may comprise any computer readable storage media readable and writeable by processing system 702 and capable of storing software 705. Storage system 703 may include volatile and nonvolatile, removable and non-removable, mutable and non-mutable media implemented in any method or technology for storage of information, such as computer readable instructions, data structures, program modules, or other data. Examples of storage media include random access memory, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 703 may also include computer readable communication media over which at least some of software 705 may be communicated internally or externally. Storage system 703 may be implemented as a single storage device but may also be implemented across multiple storage devices or sub-systems co-located or distributed relative to each other. Storage system 703 may comprise additional elements, such as a controller, capable of communicating with processing system 702 or possibly other systems.

Software 705 (including clock enablement process 706) may be implemented in program instructions and among other functions may, when executed by processing system 702, direct processing system 702 to operate as described with respect to the various operational scenarios, sequences, and processes illustrated herein. For example, software 705 may include program instructions for implementing an address space mapping process as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded environment, in a single processor or multi-processor environment, in a single host or multi-host environment, or in accordance with any other suitable execution paradigm, variation, or combination thereof. Software 705 may include additional processes, programs, or components, such as operating system software, virtualization software, or other application software. Software 705 may also comprise firmware or some other form of machine-readable processing instructions executable by processing system 702.

In general, software 705 may, when loaded into processing system 702 and executed, transform a suitable apparatus, system, or device (of which computing system 701 is representative) overall from a general-purpose computing system into a special-purpose computing system customized to provide memory access as described herein. Indeed, encoding software 705 on storage system 703 may transform the physical structure of storage system 703. The specific transformation of the physical structure may depend on various factors in different implementations of this description. Examples of such factors may include, but are not limited to, the technology used to implement the storage media of storage system 703 and whether the computer-storage media are characterized as primary or secondary storage, as well as other factors.

For example, if the computer readable storage media are implemented as semiconductor-based memory, software 705 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 707 may include communication connections and devices that allow for communication with other computing systems (not shown) over communication networks (not shown). Examples of connections and devices that together allow for inter-system communication may include network interface cards, antennas, power amplifiers, radiofrequency circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing system 701 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of networks, or variation thereof. The aforementioned communication networks and protocols are well known and need not be discussed at length here.

While some examples provided herein are described in the context of embedded systems, logic systems, device testing systems, and circuits, sub-circuits, hardware, software, firmware, electrical components and environments thereof, the systems, devices, and methods described herein are not limited to such embodiments and may apply to a variety of other processes, systems, applications, devices, and the like. Aspects of the present invention may be embodied as a system, method, computer program product, and other configurable systems. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

Example embodiments of the present disclosure are summarized here. Other embodiments can also be understood from the entirety of the specification and the claims filed herein.

Example 1. A system, including: control circuitry configured to: enable a first clock signal to drive a device-under-test coupled to a power supply, where the first clock signal includes: a first portion that includes a first set of clock cycles; a second portion that includes a second set of clock cycles; a third portion that includes a third set of clock cycles; a first idle portion between the first portion and the second portion; and a second idle portion between the second portion and the third portion; and during the first and second idle portions, enable a second clock signal supplied to a different device coupled to the power supply.

Example 2. The system of example 1, where: the first and second idle portions create noise in the power supply coupled to a device-under-test; and the second clock signal offsets the noise in the power supply.

Example 3. The system of one of examples 1 or 2, further including the device-under-test, the device-under-test configured to perform a scan-chain test during a scan cycle based on the first clock signal.

Example 4. The system of one of examples 1 to 3, where the scan cycle includes a scan-in portion, a functional capture portion, and a scan-out portion, and where the first portion of the first clock signal corresponds to the scan-in portion, the second portion of the first clock signal corresponds to the functional capture portion, and the third portion of the first clock signal corresponds to a scan-out portion.

Example 5. The system of one of examples 1 to 4, where the control circuitry is configured to, in response to detecting an end of the scan-in portion, enable the second clock signal.

Example 6. The system of one of examples 1 to 5, where the second clock signal includes a first portion that includes a fourth set of clock cycles and a second portion having a fifth set of clock cycles.

Example 7. The system of one of examples 1 to 6, where the first set of clock cycles and the third set of clock cycles include the same number of clock cycles.

Example 8. The system of one of examples 1 to 7, where the number of clock cycles of the fourth and fifth sets of clock cycles is based on a duration of the first and second idle portions, respectively.

Example 9. The system of one of examples 1 to 8, where the control circuitry is further configured to: identify a first frequency of the first clock signal; and during the first and second idle portions, enable the second clock signal at a second frequency based on the first frequency.

Example 10. The system of one of examples 1 to 9, where the control circuitry is further configured to: identify an amount of voltage received from the power supply at the device-under-test while the device-under-test is driven by the first clock signal; and during the first and second idle portions, enable the second clock signal at a frequency based on the amount of voltage.

Example 11. The system of one of examples 1 to 10, where the control circuitry is further configured to, during the first and second idle portions, enable a third clock signal supplied to the different device, where the third clock signal includes a phase-shifted set of clock cycles 180-degrees-out-of-phase relative to the first clock signal and the second clock signal.

Example 12. A device, including: a processor coupled with one or more computer readable storage media; and program instructions stored on the one or more computer readable storage media that, when executed, direct the processor to: enable a first clock signal to drive a device-under-test coupled to a power supply, where the first clock signal includes: a first portion that includes a first set of clock cycles; a second portion that includes a second set of clock cycles; a third portion that includes a third set of clock cycles; a first idle portion between the first portion and the second portion; and a second idle portion between the second portion and the third portion; and during the first and second idle portions, enable a second clock signal supplied to a different device coupled to the power supply.

Example 13. The device of example 12, where: the first and second idle portions create noise in the power supply coupled to a device-under-test; and the second clock signal offsets the noise in the power supply.

Example 14. The device of one of examples 12 or 13, where: the device-under-test is configured to perform a scan-chain test during a scan cycle based on the first clock signal; the scan cycle includes a scan-in portion, a functional capture portion, and a scan-out portion;

Example 15. The device of one of examples 12 to 14, where: the second clock signal includes a first portion that includes a fourth set of clock cycles and a second portion having a fifth set of clock cycles; the number of clock cycles of the fourth and fifth sets of clock cycles is based on a duration of the first and second idle portions, respectively.

Example 16. The device of one of examples 12 to 15, where a frequency of the second clock signal is based on one or more of: a frequency of the first clock signal, an amount of voltage received from the power supply at the device-under-test while the device-under-test is driven by the first clock signal, and an impedance of the device-under-test.

Example 17. A system, including: a first clock terminal; a second clock terminal; and control circuitry coupled to the first clock terminal and the second clock terminal, where the control circuitry is configured to: enable, via the first clock terminal, a first clock signal to drive a device-under-test coupled to a power supply, where the first clock signal includes: a first portion that includes a first set of clock cycles; a second portion that includes a second set of clock cycles; a third portion that includes a third set of clock cycles; a first idle portion between the first portion and the second portion; and a second idle portion between the second portion and the third portion; and during the first and second idle portions, enable, via the second clock terminal, a second clock signal supplied to a different device coupled to the power supply.

Example 18. The system of example 17, where: the first and second idle portions create noise in the power supply coupled to a device-under-test; and the second clock signal offsets the noise in the power supply.

Example 19. The system of one of examples 17 or 18, where: the device-under-test is configured to perform a scan-chain test during a scan cycle based on the first clock signal; the scan cycle includes a scan-in portion, a functional capture portion, and a scan-out portion; the first portion of the first clock signal corresponds to the scan-in portion; the second portion of the first clock signal corresponds to the functional capture portion; the third portion of the first clock signal corresponds to a scan-out portion; and the program instructions direct the processor to enable the second clock signal in response to detecting an end of the scan-in portion.

Example 20. The system of one of examples 17 to 19, further including a third clock terminal, where the control circuitry is further configured to, during the first and second idle portions, enable, via the third clock terminal, a third clock signal supplied to the different device, where the third clock signal includes a phase-shifted set of clock cycles 180-degrees-out-of-phase relative to the first clock signal and the second clock signal.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. A system, comprising:
control circuitry configured to:
enable a first clock signal to drive a device-under-test coupled to a power supply, wherein the first clock signal comprises:
a first portion that includes a first set of clock cycles;
a second portion that includes a second set of clock cycles;
a third portion that includes a third set of clock cycles;
a first idle portion between the first portion and the second portion; and
a second idle portion between the second portion and the third portion; and
during the first and second idle portions, enable a second clock signal supplied to a different device coupled to the power supply.

2. The system of claim 1, wherein:
the first and second idle portions create noise in the power supply coupled to a device-under-test; and
the second clock signal offsets the noise in the power supply.

3. The system of claim 1, further comprising the device-under-test, the device-under-test configured to perform a scan-chain test during a scan cycle based on the first clock signal.

4. The system of claim 3, wherein the scan cycle comprises a scan-in portion, a functional capture portion, and a scan-out portion, and wherein the first portion of the first clock signal corresponds to the scan-in portion, the second portion of the first clock signal corresponds to the functional capture portion, and the third portion of the first clock signal corresponds to a scan-out portion.

5. The system of claim 4, wherein the control circuitry is configured to, in response to detecting an end of the scan-in portion, enable the second clock signal.

6. The system of claim 1, wherein the second clock signal comprises a first portion that includes a fourth set of clock cycles and a second portion having a fifth set of clock cycles.

7. The system of claim 6, wherein the first set of clock cycles and the third set of clock cycles include the same number of clock cycles.

8. The system of claim 7, wherein the number of clock cycles of the fourth and fifth sets of clock cycles is based on a duration of the first and second idle portions, respectively.

9. The system of claim 7, wherein the control circuitry is further configured to:
identify a first frequency of the first clock signal; and
during the first and second idle portions, enable the second clock signal at a second frequency based on the first frequency.

10. The system of claim 7, wherein the control circuitry is further configured to:
identify an amount of voltage received from the power supply at the device-under-test while the device-under-test is driven by the first clock signal; and
during the first and second idle portions, enable the second clock signal at a frequency based on the amount of voltage.

11. The system of claim 1, wherein the control circuitry is further configured to, during the first and second idle portions, enable a third clock signal supplied to the different device, wherein the third clock signal comprises a phase-shifted set of clock cycles 180-degrees-out-of-phase relative to the first clock signal and the second clock signal.

12. A device, comprising:
a processor coupled with one or more computer readable storage media; and
program instructions stored on the one or more computer readable storage media that, when executed, direct the processor to:
enable a first clock signal to drive a device-under-test coupled to a power supply, wherein the first clock signal comprises:
a first portion that includes a first set of clock cycles;
a second portion that includes a second set of clock cycles;
a third portion that includes a third set of clock cycles;
a first idle portion between the first portion and the second portion; and
a second idle portion between the second portion and the third portion; and
during the first and second idle portions, enable a second clock signal supplied to a different device coupled to the power supply.

13. The device of claim 12, wherein:
the first and second idle portions create noise in the power supply coupled to a device-under-test; and
the second clock signal offsets the noise in the power supply.

14. The device of claim 12, wherein:
the device-under-test is configured to perform a scan-chain test during a scan cycle based on the first clock signal;
the scan cycle comprises a scan-in portion, a functional capture portion, and a scan-out portion;
the first portion of the first clock signal corresponds to the scan-in portion;
the second portion of the first clock signal corresponds to the functional capture portion;
the third portion of the first clock signal corresponds to a scan-out portion; and
the program instructions direct the processor to enable the second clock signal in response to detecting an end of the scan-in portion.

15. The device of claim 12, wherein:
the second clock signal comprises a first portion that includes a fourth set of clock cycles and a second portion having a fifth set of clock cycles;
the number of clock cycles of the fourth and fifth sets of clock cycles is based on a duration of the first and second idle portions, respectively.

16. The device of claim 15, wherein a frequency of the second clock signal is based on one or more of: a frequency of the first clock signal, an amount of voltage received from the power supply at the device-under-test while the device-under-test is driven by the first clock signal, and an impedance of the device-under-test.

17. A system, comprising:
a first clock terminal;
a second clock terminal; and
control circuitry coupled to the first clock terminal and the second clock terminal, wherein the control circuitry is configured to:
enable, via the first clock terminal, a first clock signal to drive a device-under-test coupled to a power supply, wherein the first clock signal comprises:
a first portion that includes a first set of clock cycles;
a second portion that includes a second set of clock cycles;
a third portion that includes a third set of clock cycles;
a first idle portion between the first portion and the second portion; and
a second idle portion between the second portion and the third portion; and
during the first and second idle portions, enable, via the second clock terminal, a second clock signal supplied to a different device coupled to the power supply.

18. The system of claim 17, wherein:
the first and second idle portions create noise in the power supply coupled to a device-under-test; and
the second clock signal offsets the noise in the power supply.

19. The system of claim 17, wherein:
the device-under-test is configured to perform a scan-chain test during a scan cycle based on the first clock signal;
the scan cycle comprises a scan-in portion, a functional capture portion, and a scan-out portion;
the first portion of the first clock signal corresponds to the scan-in portion;
the second portion of the first clock signal corresponds to the functional capture portion;
the third portion of the first clock signal corresponds to a scan-out portion; and
the program instructions direct the processor to enable the second clock signal in response to detecting an end of the scan-in portion.

20. The system of claim 17, further comprising a third clock terminal, wherein the control circuitry is further configured to, during the first and second idle portions, enable, via the third clock terminal, a third clock signal supplied to the different device, wherein the third clock signal comprises a phase-shifted set of clock cycles 180-degrees-out-of-phase relative to the first clock signal and the second clock signal.
